(19) United States
(12) Patent Application Publication
(10) Pub. No.: US 2022/0392538 A1
(43) Pub. Date: Dec. 8, 2022

(54) MEMORY DEVICE AND OPERATING METHOD THEREOF

(71) Applicant: SK hynix Inc., Icheon-si Gyeonggi-do (KR)

(72) Inventor: Jae Il TAK, Icheon-si Gyeonggi-do (KR)

(73) Assignee: SK hynix Inc., Icheon-si Gyeonggi-do (KR)

(21) Appl. No.: 17/518,380

(22) Filed: Nov. 3, 2021

(30) Foreign Application Priority Data
Jun. 2, 2021 (KR) 10-2021-0071814

(51) Int. Cl. G11C 16/10; G11C 16/04; G11C 16/20; G11C 16/34

(52) U.S. Cl. CPC G11C 16/10; G11C 16/0483; G11C 16/20; G11C 16/3459

(57) ABSTRACT

A memory device includes a memory cell array with a plurality of memory cells that are connected to a plurality of word lines and a plurality of strings; and a peripheral circuit for performing a program operation on selected memory cells, among the plurality of memory cells, connected to a selected word line. While the peripheral circuit applies a pass voltage to the selected word line during the program operation to turn on the selected memory cells, the peripheral circuit is configured to apply a select voltage to an unselected source line to turn on a source select transistor and configured to apply a ground voltage to an unselected drain select line.

### CROSS-REFERENCE TO RELATED APPLICATION

The present application claims priority under 35 U.S.C, § 119(a) to Korean patent application number 10-2021-0071814, filed on Jun. 2, 2021, in the Korean intellectual Property Office, the entire disclosure of which is incorporated herein by reference.

### BACKGROUND

### 1. Technical Field

The present disclosure generally relates to an electronic device, and more particularly, to a memory device and an operating method thereof.

### 2. Related Art

A storage device, under the control of a host device, is a device that stores data, such as a computer or a smart phone. The storage device may include a memory device for storing data and a memory controller for controlling the memory device. The memory device is classified into a volatile memory device and a nonvolatile memory device.

The volatile memory device is a memory device in which data is stored only when power is supplied, and stored data disappears when the supply of power is interrupted. The volatile memory device may include a Static Random Access Memory (SRAM), a Dynamic Random Access Memory (DRAM), and the like.

The nonvolatile memory device is a memory device in which data does not disappear even when the supply of power is interrupted. The nonvolatile memory device may include a Read Only Memory (ROM), a Programmable ROM (PROM), an Electrically Programmable ROM (EPROM), an Electrically Erasable ROM (EEROM), a flash memory, and the like.

### SUMMARY

In accordance with an aspect of the present disclosure, there is provided a memory device including a memory cell array with a plurality of memory cells that are connected to a plurality of word lines and a plurality of strings; and a peripheral circuit configured to perform a program operation on selected memory cells, among the plurality of memory cells, connected to a selected word line, wherein, while the peripheral circuit applies a pass voltage to the selected word line during the program operation to turn on the selected memory cells, the peripheral circuit is configured to apply a select voltage to an unselected source line and is configured to apply a ground voltage to an unselected drain select line.

In accordance with another aspect of the present disclosure, there is provided a method for operating a memory device with a plurality of memory cells that are connected to a plurality of word lines and a plurality of strings, the method including: performing a program voltage application operation that applies a program voltage to a selected word line, among the plurality of word lines; performing a channel initialization operation on unselected strings, among the plurality of strings, by applying a turn-on voltage to a source select line of the unselected strings, among the plurality of strings, and applying a ground voltage to a drain select line of the unselected strings; and performing a verify operation that applies a verify voltage to the selected word line.

In accordance with still another aspect of the present disclosure, there is provided a memory device including a memory cell array with a plurality of memory cells that are connected to a plurality of word lines and a plurality of strings; and a peripheral circuit configured to: apply a program voltage to a selected word line, among the plurality of word lines, and apply a pass voltage to the selected word line to turn on selected memory cells that correspond to the selected word line; and then apply a select voltage to an unselected source select line to turn on a source select transistor that corresponds to an unselected source select line and apply a ground voltage to an unselected drain select line.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a diagram illustrating a storage device in accordance with an embodiment of the present disclosure.

FIG. 2 is a diagram illustrating a memory device in accordance with an embodiment of the present disclosure.

FIG. 3 is a diagram illustrating a memory block in accordance with an embodiment of the present disclosure.

FIG. 4 is a diagram illustrating a memory block in accordance with an embodiment of the present disclosure.

FIG. 5 is a diagram illustrating a memory block in accordance with an embodiment of the present disclosure.

FIG. 6 is a diagram illustrating a program operation in accordance with an embodiment of the present disclosure.

FIG. 7 is a diagram illustrating a program loop in accordance with an embodiment of the present disclosure.

FIG. 8 is a timing diagram of a program operation in accordance with an embodiment of the present disclosure.

FIG. 9 is a timing diagram of a program operation in accordance with an embodiment of the present disclosure.

FIG. 10 is a sectional view of a string at any time during a program operation in accordance with an embodiment of the present disclosure.

FIG. 11 is a sectional view of a string at any time during a program operation in accordance with an embodiment of the present disclosure.

FIG. 12 is a flowchart illustrating an operating method of the memory device in accordance with an embodiment of the present disclosure.

FIG. 13 is a diagram illustrating a memory controller in accordance with an embodiment of the present disclosure.

FIG. 14 is a diagram illustrating a memory card system in accordance with an embodiment of the present disclosure.

FIG. 15 is a diagram illustrating a Solid State Drive (SSD) in accordance with an embodiment of the present disclosure.

FIG. 16 is a diagram illustrating a user system in accordance with an embodiment of the present disclosure.

### DETAILED DESCRIPTION

The specific structural or functional description disclosed herein is merely illustrative for the purpose of describing embodiments according to the concept of the present disclosure. The embodiments according to the concept of the present disclosure can be implemented in various forms, and cannot be construed as limited to the embodiments set forth herein.

Embodiments provide a memory device for performing an improved program operation and an operating method of the memory device.

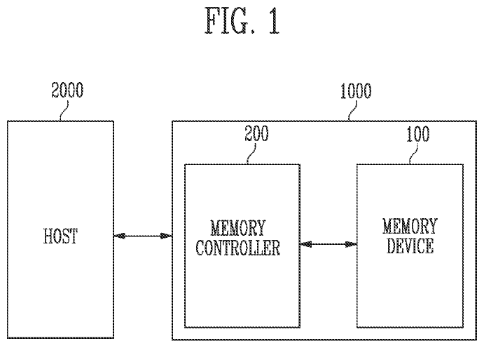

FIG. 1 is a diagram illustrating a storage device in accordance with an embodiment of the present disclosure.

Referring to FIG. 1, the storage device 1000 may include a memory device 100 and a memory controller 200.

The storage device 1000, under the control of a host 2000, may be a device that stores data, such as a mobile phone, a smart phone, an MP3 player, a laptop computer, a desktop computer, a game console, a display device, a tablet PC or an in-vehicle infotainment.

The storage device 1000 may be manufactured as any one of various types of storage devices according to a host interface that is the means for communication with the host 2000, For example, the storage device 1000 may be implemented with any one of the following variety of types of storage devices: a Solid State Drive (SSD), a Multi-Media Card (MMC), an Embedded MMC (eMMC), a Reduced Size MMC (RS-MMC), a micro-MMC (micro-MMC), a Secure Digital (SD) card, a mini-SD card, a micro-SD card, a Universal Serial Bus (USB) storage device, a Universal Flash Storage (UFS) device, a Compact Flash (CF) card, a Smart Media Card (SMC), a memory stick, and the like.

The storage device 1000 may be implemented as any one of various kinds of package types. For example, the storage device 1000 may be implemented as any one of the following various kinds of package types: a Package-On-Package (POP), a System-In-Package (SIP), a System-On-Chip (SOC), a Multi-Chip Package (MCP), a Chip-On-Board (COB), a Wafer-level Fabricated Package (WFP), a Wafer-level Stack Package (WSP), and the like.

The memory device 100 may store data or use stored data. The memory device 100 may operate under the control of the memory controller 200. Furthermore, the memory device 100 may include a plurality of memory dies, and each of the plurality of memory dies may include a memory cell array with a plurality of memory cells that store data.

Each of the memory cells may be configured as a Single Level Cell (SLC) that stores one data bit, a Multi-Level Cell (MLC) that stores two data bits, a Triple Level Cell (TLC) that stores three data bits, or a Quad Level Cell (QLC) that stores four data bits.

The memory cell array may include a plurality of memory blocks. Each memory block may include a plurality of memory cells, and one memory block may include a plurality of pages. The page may be a unit for storing data in the memory device 100 or reading data that is stored in the memory device 100.

The memory device 100 may be implemented as a Double Data Rate Synchronous Dynamic Random Access Memory (DDR SDRAM), a Low Power Double Data Rate 4 (LPDDR4) SDRAM, a Graphics Double Data Rate (DDDR) SRAM, a Low Power DDR (LPDDR), a Rambus Dynamic Random Access Memory (RDRAM), a NAND flash memory, a vertical NAND flash memory, a NOR flash memory, a Resistive Random Access Memory (RRAM), a Phase-Change Random Access Memory (PRAM), a Magnetoresistive Random Access Memory (MRAM), a Ferroelectric Random Access Memory (FRAM), a Spin Transfer Torque Random Access Memory (STT-RAM), or the like. In this specification, for convenience of description, the case in which the memory device 100 is a NAND flash memory is assumed and described.

The memory device 100 may receive a command and an address from the memory controller 200. The memory device 100 may access an area that is selected by the received address in the memory cell array. That the memory device 100 may access the selected area may mean that the memory device 100 may perform an operation that corresponds to the received command on the selected area. For example, the memory device 100 may perform a write operation (program operation), a read operation, and an erase operation. The program operation may be an operation in which the memory device 100 records data in the area that is selected by the address. The read operation may mean an operation in which the memory device 100 reads data from the area that is selected by the address. The erase operation may mean an operation in which the memory device 100 erases data that is stored in the area that is selected by the address.

In accordance with an embodiment of the present disclosure, the memory device 100 may maintain a Boosting SSL Switching Read (BSSR) effect of an unselected string, but may initialize a channel potential. Specifically, before the memory device 100 enters into a verify phase in a program operation, the memory device 100 may discharge the channel potential by applying a select voltage to a source select line SSL of the unselected string to turn on a source select transistor and maintain the BSSR effect of the unselected string by applying a ground voltage to a drain select line DSL of the unselected string, but may initialize the channel potential. Alternatively, in the verify phase in the program operation, the memory device 100 may discharge the channel potential by applying the select voltage to the source select line SSL of the unselected string to turn on the source select transistor and may prevent the channel potential from approaching a bit line and a page buffer by applying the ground voltage to the drain select line DSL of the unselected string.

The memory controller 200 may control the overall operations of the storage device 1000. Specifically, when power is applied to the storage device 1000, the memory controller 200 may execute firmware (FW). The FW may include a Host Interface Layer (HIL), which receives a request that is input from the host 2000 or outputs a response to the host 2000, a Flash Translation Layer (FTL) which manages an operation between an interface of the host 2000 and an interface of the memory device 100, and a Flash Interface Layer (FIL) which provides a command to the memory device 100 or receives a response from the memory device 100.

The memory controller 200 may receive data and a Logical Address (LA) from the host 2000 and may translate the LA into a Physical Address (PA) that represents an address of memory cells in which data that is included in the memory device 100 is to be stored. The LA may be a Logical Block Address (LBA), and the PA may be a Physical Block Address (PBA).

The memory controller 200 may control the memory device 100 to perform a program operation, a read operation, an erase operation, or the like in response to a request from the host 2000. In the program operation, the memory controller 200 may provide a program command, a PBA, and data to the memory device 100. In the read operation, the memory controller 200 may provide a read command and a PBA to the memory device 100. In the erase operation, the memory controller 200 may provide an erase command and a PBA to the memory device 100.

The memory controller 200 may control the memory device 100 to autonomously perform a program operation, a read operation, or an erase operation regardless of any requests from the host 2000. For example, the memory controller 200 may control the memory device 100 to perform a program operation, a read operation, or an erase operation, which is used to perform a background operation, such as wear leveling, garbage collection, or read reclaim.

The host 2000 may communicate with the storage device 1000, using at least one of the following various communication manners: a Universal Serial bus (USB), a Serial AT Attachment (SATA), a High Speed InterChip (HSIC), a Small Computer System Interface (SCSI), Firewire, a Peripheral Component Interconnection (PCI), a PCI express (PCIe), a Non-Volatile Memory express (NVMe), a universal flash storage (UFS), a Secure Digital (SD), a Multi-Media Card (MMC), an embedded MMC (eMMC), a Dual In-line Memory Module (DIMM), a Registered DIMM (RDIMM), a Load Reduced DIMM (LRDIMM), and the like.

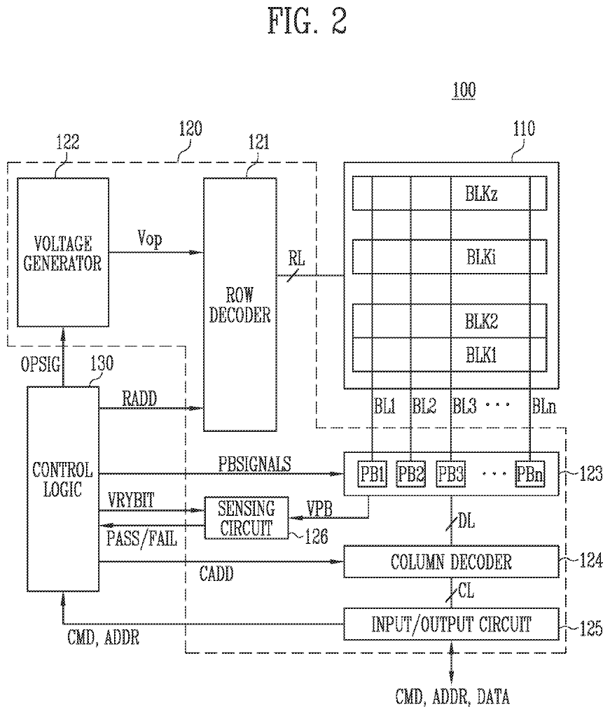

FIG. 2 is a diagram illustrating a memory device in accordance with an embodiment of the present disclosure.

Referring to FIG. 2, the memory device 100 may include a memory cell array 110, a peripheral circuit 120, and a control logic 130.

The memory cell array 110 may include a plurality of memory blocks BLK1 to BLKz. The plurality of memory blocks BLK1 to BLKz may be connected to a row decoder 121 through row lines RL. The row lines RL may include at least one source select line, a plurality of word lines, and at least one drain select line. The plurality of memory blocks BLK1 to BLKz may be connected to a page buffer group 123 through bit lines BL1 to BLn. Each of the plurality of memory blocks BLK1 to BLKz may include a plurality of memory cells. In an embodiment, the plurality of memory cells may be nonvolatile memory cells. Memory cells that are connected to the same word line may be defined as one page. Therefore, one memory block may include a plurality of pages.

Each of the memory cells that are included in the memory cell array 110 may be configured as a Single Level Cell (SLC) storing one data bit, a Multi-Level Cell (MLC) storing two data bits, a Triple Level Cell (TLC) storing three data bits, or a Quadruple Level Cell (QLC) storing four data bits.

The peripheral circuit 120, under the control of the control logic 130, may be configured to perform a program operation, a read operation, or an erase operation on a selected area of the memory cell array 110. That is, the peripheral circuit 120, under the control of the control logic 130, may drive the memory cell array 110. For example, the peripheral circuit 120, under the control of the control logic 130, may apply various operating voltages to the row lines RL and the bit lines BL1 to BLn or may discharge the applied voltages.

Specifically, the peripheral circuit 120 may include the row decoder 121, a voltage generator 122, the page buffer group 123, a column decoder 124, an input/output circuit 125, and a sensing circuit 126.

The row decoder 121 may be connected to the memory cell array 110 through the row lines RL. The row lines RL may include at least one source select line, a plurality of word lines, and at least one drain select line. In an embodiment, the word lines may include norm& word lines and dummy word lines. In an embodiment, the row lines RL may further include a pipe select line.

The row decoder 121 may operate under the control of the control logic 130. The row decoder 121 may receive a row address RADA from the control logic 130. Specifically, the row decoder 121 may decode the row address RADD. The row decoder 121 may select at least one memory block, among the memory blocks BLK1 to BLKz, according to the decoded address. Furthermore, the row decoder 121 may select at least one word line of the selected memory block to apply voltages generated by the voltage generator 122 to the at least one word line WL according the decoded address.

For example, in a program operation, the row decoder 121 may apply a program voltage to the selected word line, and apply a program pass voltage with a voltage level that is lower than a voltage level of the program voltage to unselected word lines. In a program verify operation, the row decoder 121 may apply a verify voltage to the selected word line and may apply a verify pass voltage with a voltage level that is higher than a voltage level of the verify voltage to the unselected word lines. In a read operation, the row decoder 121 may apply a read voltage to the selected word line and may apply a read pass voltage higher than the read voltage.

In an embodiment, an erase operation of the memory device 100 may be performed in a memory block unit. In the erase operation, the row decoder 121 may select one memory block according to the decoded address. In the erase operation, the row decoder 121 may apply a ground voltage to word lines that are connected to the selected memory block.

The voltage generator 122 may operate under the control of the control logic 130, Specifically, the voltage generator 122, under the control of the control logic 130, may generate a plurality of voltages by using an external power voltage that is supplied to the memory device 100. For example, the voltage generator 122 may generate a program voltage, a verify voltage, a pass voltage, a read voltage, an erased voltage, and the like under the control of the control logic 130. That is, the voltage generator 122 may generate various operating voltages Vop that are used in program, read, and erase operations in response to an operation signal OPSIG.

In an embodiment, the voltage generator 122 may generate an internal power voltage by regulating the external power voltage. The internal power voltage that is generated by the voltage generator 122 may be used as an operation voltage of the memory cell array 110.

In an embodiment, the voltage generator 122 may generate a plurality of voltages by using the external power voltage or the internal power voltage. For example, the voltage generator 122, under the control of the control logic 130, may include a plurality of pumping capacitors that receive the internal power voltage and may generate the plurality of voltages by selectively activating the plurality of pumping capacitors. In addition, the plurality of generated voltages may be supplied to the memory cell array 110 by the row decoder 121.

The page buffer group 123 may include first to nth page buffers PB1 to PBn. The first to nth page buffers PB1 to PBn may be connected to the memory cell array 110, respectively, through first to nth bit lines BL1 to BLn. Furthermore, the first to nth bit lines BL1 to BLn may operate under the control of the control logic 130. Specifically, the first to nth bit lines BL1 to BLn may operate in response to page buffer control signals PBSIGNALS. For example, the first to nth page buffers PB1 to PBn may temporarily store data that is received through the first to nth bit lines BL1 to BLn, or sense a voltage or current of the bit lines BL1 to BLn in a read or verify operation.

Specifically, in a program operation, the first to nth page buffers PB1 to PBn may transfer data DATA that is received through the input/output circuit 125 to selected memory cells through the first to nth bit lines BL1 to BLn when a program voltage is applied to a selected word line. Memory cells of a selected page may be programmed according to the transferred data DATA. A memory cell that is connected to a bit line to which a program allow voltage (e.g., a ground voltage) is applied may have an increased threshold voltage. A threshold voltage of a memory cell that is connected to a bit line to which a program inhibit voltage (e.g., a power voltage) is applied may be maintained,

In a program verify operation, the first to nth page buffers PB1 to PBn may read page data from the selected memory cells through the first to nth bit lines BL1 to BLn.

In a read operation, the first to nth page buffers PB1 to PBn, under the control of the column decoder 124, may read data DATA from the memory cells of the selected page through the first to nth bit lines BL1 to BLn and may output the read data DATA to the input/output circuit 125.

In an erase operation, the first to nth page buffers PB1 to PBn may float the first to nth bit lines BL1 to BLn.

The column decoder 124 may communicate data between the input/output circuit 125 and the page buffer group 123 in response to a column address CADD. For example the column decoder 124 may communicate data with the first to nth page buffers PB1 to PBn through data lines DL, or communicate data with the input/output circuit 125 through column lines CL.

The input/output circuit 125 may transfer a command CMD and an address ADDR, which are received from the memory controller 200, to the control logic 130, or exchange data DATA with the column decoder 124.

In a read operation or verify operation, the sensing circuit 126 may generate a reference current in response to an allow bit VRYBIT signal, and output a pass PASS or a fail signal FAIL by comparing a sensing voltage VPB that is received from the page buffer group 123 and a reference voltage that is generated by the reference current.

The control logic 130 may control the peripheral circuit 120 by outputting the operation signal OPSIG, the row address RADD, the page buffer control signals PBSIGNALS, and the allow bit VRYBIT in response to the command CMD and the address ADDR.

Furthermore, the control logic 130 may determine whether the verify operation has passed or failed in response to the pass or fail signal PASS or FAIL. Additionally, the control logic 130 may control the page buffer group 123 to temporarily store verify information, including the pass or fail signal PASS or FAIL, in the page buffer group 123. Specifically, the control logic 130 may determine a program state of a memory cell in response to the pass signal PASS or the fail signal FAIL. For example, when the memory cell operates as a Triple Level Cell (TLC), the control logic 130 may determine whether the program state of the memory cell is an erase state E or any one of first to seventh program states P1 to P7.

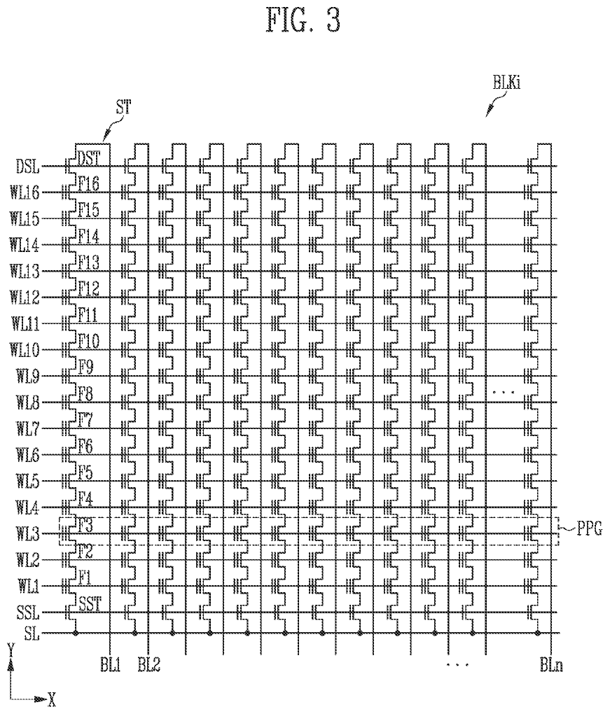

FIG. 3 is a diagram illustrating a memory block in accordance with an embodiment of the present disclosure.

Referring to FIG. 3, in the memory block BLKi, a plurality of word lines that are arranged in parallel to each other may be connected between a first select line and a second select line. The first select line may be a source select line SSL, and the second select line may be a drain select line DSL. More specifically, the memory block BLKi may include a plurality of strings ST that are connected between bit lines BL1 to BLn and a source line SL. The bit lines BL1 to BLn may be respectively connected to the strings ST, and the source line SL may be commonly connected to the strings ST. The strings ST may be configured identically to one another, and therefore, a string ST that is connected to a first bit line BL1 will be described in detail as an example,

The string ST may include a source select transistor SST, a plurality of memory cells F1 to F16, and a drain select transistor DAT, which are connected in series to each other between the source line SL and the first bit line BL1. At least one source select transistor SST and at least one drain select transistor DST may be included in one string ST, and memory cells of which number is greater than the number of the memory cells F1 to F16 shown in the drawing may be included in the one string ST.

A source of the source select transistor SST may be connected to the source line SL, and a drain of the drain select transistor DST may be connected to the first bit line BL1. The memory cells MC1 to MC16 may be connected in series between the source select transistor SST and the drain select transistor DST. Gates of source select transistors SST that are included in different strings ST may be connected to the source select line SSL, and gates of drain select transistors DST that are included in different strings ST may be connected to the drain select line DSL. Gates of the memory cells F1 to F16 may be connected to a plurality of word lines WL1 to WL16. A group of memory cells, among memory cells that are included in different strings ST, connected to the same word line, cells that are included may be referred to as a physical page PPG. Therefore, physical pages PPG that correspond to the number of the word lines WL1 to WL16 may be included in the memory block BLKi.

Each of the memory cells may be configured as a Single Level Cell (SLC) that stores one data bit, a Mufti-Level Cell (MLC) that stores two data bits, a Triple Level Cell (TLC) that stores three data bits, or a Quad Level Cell (QLC) that stores four data bits.

The SLC may store one-bit data. One physical page PG of the SLC may store one logical page (LPG) data. The one LPG data may include data bits, the number of which corresponds to the cells that are included in the one physical page PG.

The MLC, the TLC, and the QLC may store two or more-bit data. One physical page PG may store two or more LPG data.

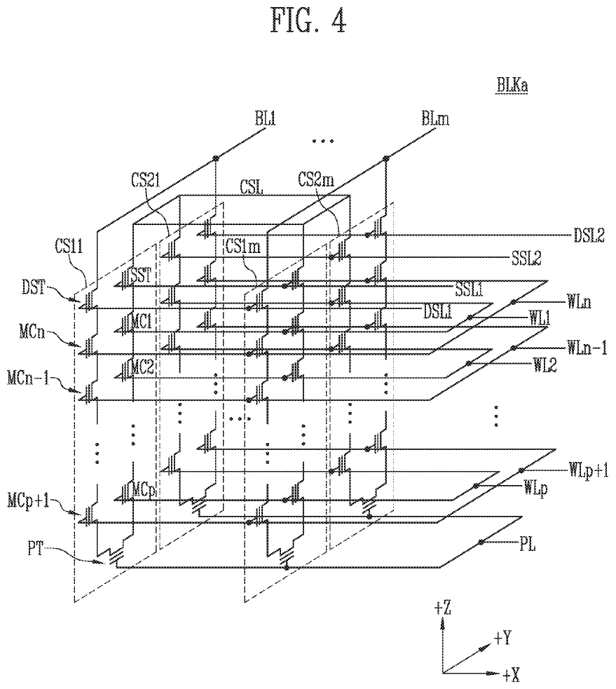

FIG. 4 is a diagram illustrating a memory block in accordance with an embodiment of the present disclosure.

Referring to FIG, 4, any one memory block BLKa, among the memory blocks BLK1 to BLKz, shown in FIG. 2, is illustrated. The memory block BLKa may include a plurality of cell strings CS11 to CS1m and CS21 to CS2m. In an embodiment, each of the plurality of cell strings CS11 to CS1m and CS21 to CS2m may be formed in a ‘U’ shape. In the memory block BLKa, m cell strings may be arranged in a row direction (i.e., a +X direction).

Meanwhile, although a case in which two cell strings that are arranged in a column direction (i.e., a +Y direction) is illustrated in FIG. 4, this is for convenience of description, and it will be apparent that three cell strings may be arranged in the column direction.

Each of the plurality of cell strings CS11 to CS1m and CS21 to CS2m may include at least one source select transistor SST, first to nth memory cells MC1 to MCn, a pipe transistor PT, and at least one drain select transistor DST.

The select transistors SST and DST and the memory cells MC1 to MCn may have structures that are similar to one another. In an embodiment, each of the select transistors SST and DST and the memory cells MC1 to MCn may include a channel layer, a tunneling insulating layer, a charge storage layer, and a blocking insulating layer. In an embodiment, a pillar for providing the channel layer may be provided in each cell string. In an embodiment, a pillar for providing at least one of the channel layer, the tunneling insulating layer, the charge storage layer, and the blocking insulating layer may be provided in each cell string.

The source select transistor SST of each cell string may be connected between a common source line CSL and memory cells MC1 to MCp.

In an embodiment, the source select transistors of cell strings that are arranged on the same row may be connected to a source select line that extends in the row direction, and the source select transistors of cell strings that are arranged on different rows may be connected to different source select lines. Referring to FIG. 4, the source select transistors of the cell strings CS11 to CS1m on a first row may be connected to a first source select line SSL1. The source select transistors of the cell strings CS21 to CS2m on a second row may be connected to a second source select line SSL2.

In another embodiment, the source select transistors of the cell strings CS11 to CS1m and CS21 to CS2m may be commonly connected to one source select line.

The first to nth memory cells MC1 to MCn of each cell string may be connected between the source select transistor SST and the drain select transistor DST.

The first to nth memory cells MC1 to MCn may be divided into first to pth memory cells MC1 to MCp and a (p+1)th to nth memory cells MCp+1 to MCn. The first to pth memory cells MC1 to MCp may be sequentially arranged in the opposite direction of a +Z direction and may be connected in series between the source select transistor SST and the pipe transistor PT. The (p+1)th to nth memory cells MCp+1 to MCn may be sequentially arranged in the +Z direction and may be connected in series between the pipe transistor PT and the drain select transistor DST. The first to pth memory cells MC1 to MCp and the (p+1)th to nth memory cells MCp+1 to MCn may be connected through the pipe transistor PT. Gate electrodes of the first to nth memory cells MC1 to MCn of each cell string may be connected to first to nth word lines WL1 to WLn, respectively.

A gate of the pipe transistor PT of each cell string may be connected to a pipe line PL.

The drain select transistor DST of each cell string may be connected between a corresponding bit line and the memory cells MCp+1 to MCn. Cell strings that are arranged in the row direction may be connected to a drain select line that extends in the row direction. The drain select transistors of the cell strings CS11 to CS1m on the first row may be connected to a first drain select line DSL1. The drain select transistors of the cell strings CS21 to CS2m on the second row may be connected to a second drain select line DSL2.

Cell strings that are arranged in the column direction may be connected to a bit line that extends in the column direction. Referring to FIG. 4, the cell strings CS11 and CS21 on a first column may be connected to a first bit line BL1. The cell strings CS1m and CS2m on an mth column may be connected to an mth bit line BLm.

Memory cells that are connected to the same word line in the cell strings that are arranged in the row direction may constitute one page. For example, memory cells that are connected to the first word line WL1 in the cell strings CS11 to CS1m on the first row may constitute one page. Memory cells that are connected to the first word line WL1 in the cell strings CS21 to CS2m on the second row may constitute another page. As any one of the drain select lines DSL1 and DSL2 is selected, cell strings that are arranged in one row direction may be selected. As any one of the word lines WL1 to WLn is selected, one page may be selected in the selected cell strings.

In another embodiment, even bit lines and odd bit lines may be provided instead of the first to mth bit lines BL1 to BLm. In addition, even-numbered cell strings, among the cell strings CS11 to CS1m or CS21 to CS2m, arranged in the row direction, may be connected to the even bit lines, respectively, and odd-numbered cell strings, among the cell strings CS11 to CS1m or CS21 to CS2m, arranged in the row direction, may be connected to the odd bit lines, respectively.

In an embodiment, at least one of the first to nth memory cells MC1 to MCn may be used as a dummy memory cell. For example, the at least one dummy memory cell may be provided to decrease an electric field between the source select transistor SST and the memory cells MC1 to MCp. Alternatively, the at least one dummy memory cell may be provided to decrease an electric field between the drain select transistor DST and the memory cells MCp+1 to MCn. When the number of dummy memory cells increases, the reliability of an operation of the memory block BLKa is improved. On the other hand, the size of the memory block BLKa increases. When the number of dummy memory cells decreases, the size of the memory block BLKa decreases. On the other hand, the reliability of an operation of the memory block BLKa may be deteriorated.

In order to efficiently control the at least one dummy memory cell, the dummy memory cells may have a required threshold voltage. Before or after an erase operation of the memory block BLKa, a program operation may be performed on all or some of the dummy memory cells. When an erase operation is performed after the program operation is performed, the threshold voltage of the dummy memory cells control a voltage that is applied to the dummy word lines that are connected to the respective dummy memory cells, so that the dummy memory cells can have the required threshold voltage.

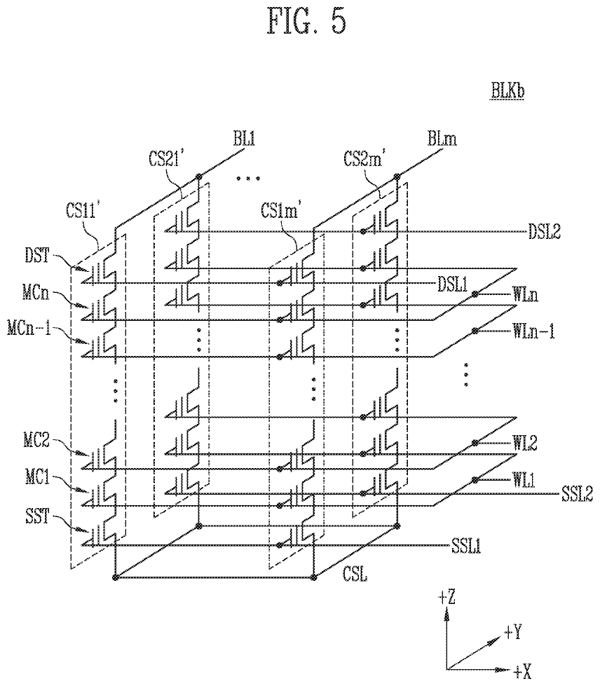

FIG. 5 is a diagram illustrating a memory block in accordance with an embodiment of the present disclosure.

Referring to FIG. 5, another embodiment BLKb of the one memory block, among the memory blocks BLK1 to BLKz, shown in FIG. 2, is illustrated. The memory block BLKb may include a plurality of cell strings CS11′ to CS1m′ and CS21′ to CS2m′. Each of the plurality of cell strings CS11′ to CS1m′ and CS21′ to CS2m′ may extend along the +Z direction. Each of the plurality of cell strings CS11′ to CS1m′ and CS21′ to CS2m′ may include at least one source select transistor SST, first to nth memory cells MC1 to MCn, and at least one drain select transistor DST, which are stacked on a substrate (not shown) under the memory block BLKb.

The source select transistor SST of each cell string may be connected between a common source line CSL and the memory cells MC1 to MCn. The source select transistors of cell strings that are arranged on the same row may be connected to the same source select line. The source select transistors of the cell strings CS11′ to CS1m′ that are arranged on a first row may be connected to a first source select line SSL1. Source select transistors of the cell strings CS21′ to CS2m′ that are arranged on a second row may be connected to a second source select line SSL2. In another embodiment, the source select transistors of the cell strings CS11′ to CS1m′ and CS21′ to CS2m′ may be commonly connected to one source select line.

The first to nth memory cells MC1 to MCn of each cell string may be connected in series between the source select transistor SST and the drain select transistor DST. Gate electrodes of the first to nth memory cells MC1 to MCn may be connected to first to nth word lines WL1 to WLn, respectively.

The drain select transistor DST of each cell string may be connected between a corresponding bit line and the memory cells MC1 to MCn. The drain select transistors of cell strings that are arranged in the row direction may be connected to a drain select line that extends in the row direction. The drain select transistors of the cell strings CS11′ to CS1m′ on the first row may be connected to a first drain select line DSL1. The drain select transistors of the cell strings CS21′ to CS2m′ on the second row may be connected to a second drain select line DSL2.

Consequently, the memory block BLKb of FIG. 5 may have a circuit that is similar to that of the memory block BLKa of FIG. 4, except that the pipe transistor PT is excluded from each cell string in FIG. 5.

In another embodiment, even bit lines and odd bit lines may be provided instead of the first to mth bit lines BL1 to BLm. In addition, even-numbered cell strings, among the cell strings CS11′ to CS1m′ or CS21′ to CS2m′, arranged in the row direction, may be connected to the even bit lines, respectively, and odd-numbered cell strings, among the cell strings CS11′ to CS1m′ or CS21′ to CS2m′, arranged in the row direction, may be connected to the odd bit lines, respectively.

In an embodiment, at least one of the first to nth memory cells MC1 to MCn may be used as a dummy memory cell. For example, the at least one dummy memory cell may be provided to decrease an electric field between the source select transistor SST and the memory cells MC1 to MCp. Alternatively, the at least one dummy memory cell may be provided to decrease an electric field between the drain select transistor DST and the memory cells MCp+1 to MCn.

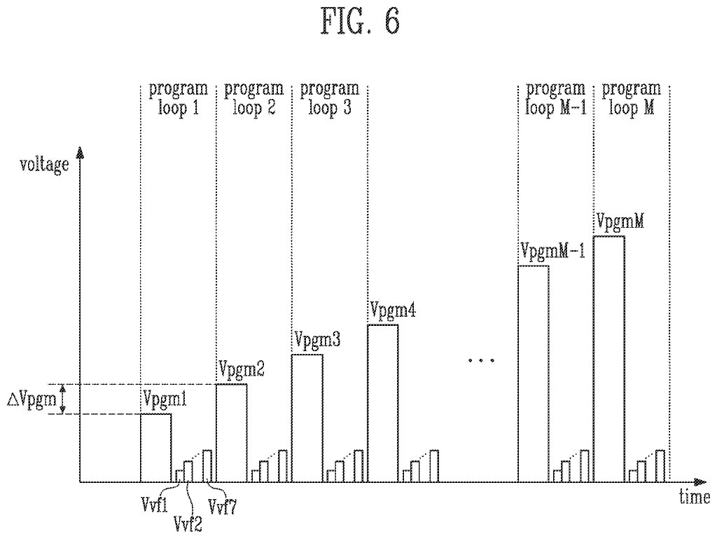

FIG. 6 is a diagram illustrating a program operation in accordance with an embodiment of the present disclosure.

Referring to FIG. 6, a program operation that forms a plurality of program states may include M program loops. Each program loop may include an operation that applies a program voltage to a selected word line and an operation that applies a verify voltage to the selected word line. The operation that applies the program voltage may be included in a program phase, and the operation that applies the verify voltage may be included in a verify phase. The operation that applies the program voltage to the selected word line may be an operation of increasing a threshold voltage of a memory cell, and the operation that applies the verify voltage may be an operation of checking whether the corresponding memory cell has reached a target program state by determining the threshold voltage. For example, a first program loop may include an operation that applies a first program voltage Vpgm1 and a plurality of verify voltages Vvf1 to Vvf7. For convenience of description, it has been illustrated that seven verify voltages are applied in all the program loops. However, the number of verify voltages is not limited thereto, and different verify voltages may be applied.

The program voltage may increase by a step voltage (ΔVpgm) as a program loop is sequentially performed. This is referred to as an Incremental Step Pulse Program (ISPP) method. For example, a second program voltage Vpgm2 that is applied to the selected word line in a second program loop may be higher by the step voltage (ΔVpgm) than the first program voltage Vpgm1. For convenience of description, it is illustrated that the step voltage is fixed. However, the step voltage may be dynamically changed.

A memory cell that reaches a target program state while the M program loops are performed may be in a program inhibit state that is not to be programmed any more. Although a subsequent program loop is performed, a threshold voltage of the memory cell that is in the program inhibit state may be maintained. For example, a memory cell that has been completely programmed to the second program state P2 as the target program state in the second program loop may be in the program inhibit state in a third program loop. In an embodiment, a bit line of the memory cell that has reached the target program state may be precharged to a program inhibit voltage. When the bit line is precharged to the program inhibit voltage, a channel of the memory cell may be self-boosted by the program voltage, and the memory cell might not be programmed.

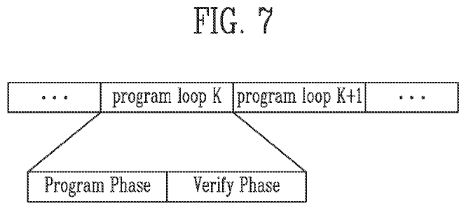

FIG. 7 is a diagram illustrating a program loop in accordance with an embodiment of the present disclosure.

Referring to FIG. 7, the program loop may include a program phase and a verify phase.

The program phase may be a period in which a program voltage is applied to a word line such that a threshold voltage of a selected memory cell is included in a target program state. The program phase may be a period in which a program sate of the selected memory cell becomes the target program state. The program phase may be a period in which a program voltage Vpgm is applied to a selected word line and a pass voltage Vpass is applied to an unselected word line.

The verify phase may be a period in which it is verified whether the program state of the selected memory cell has reached the target program state after the program phase. The verify phase may include a period in which a bit line is sensed. In the verify phase, the sensing circuit 126 may generate a reference current in response to an allow bit signal VRYBIT and may output a pass signal PASS or a fail signal FAIL by comparing a sensing voltage VPB that is received from the page buffer group 123 with a reference voltage that is generated by the reference current. The sensing circuit 126 may output the pass signal PASS or a fail signal FAIL by comparing a sensing current that is received from the page buffer group 123 with the reference current. Although it has been described that the sensing circuit 126 compares the sensing voltage VPB with the reference voltage, the circuit 126 may output the pass signal PASS or a fail signal FAIL by comparing a sensing current IPB with the reference current.

For example, when verification on the sixth program state P6 passes before a Kth program loop, the Kth program loop and program loops after the Kth program loop may be program loops for forming the seventh program state P7. Memory cells of which target program state is the sixth program state P6 may be in the program inhibit state and might not be programmed from the Kth program loop. For example, a power voltage Vcc may be applied to a bit line of a memory cell that reaches the sixth program state P6 as the target program state so that the memory cell that reaches the sixth program state P6 may be in the program inhibit state. Memory cells of which target program state is the seventh program state P7 may be in a program allow state and may be programmed from the Kth program loop. Specifically, a ground voltage GND or 0V may be applied to a bit line of a memory cell that reaches the seventh program state P7 as the target program state so that the memory cell that reaches the seventh program state P7 as the target program state may be programmed.

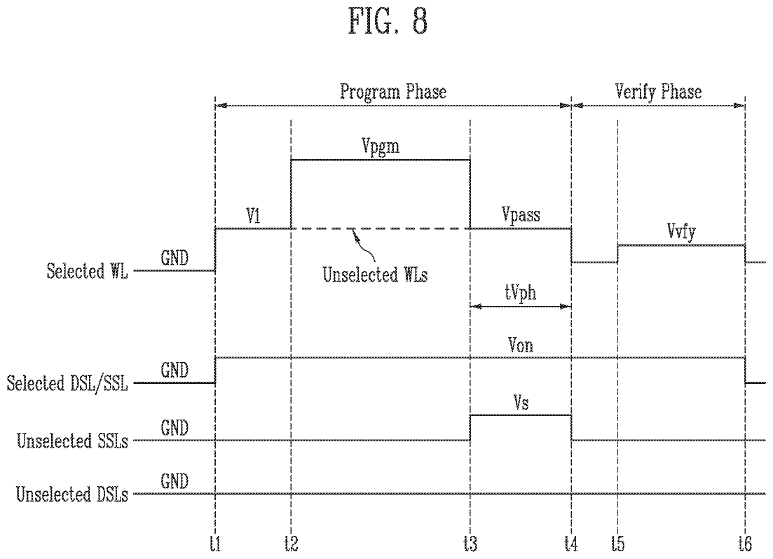

FIG. 8 is a timing diagram of a program operation in accordance with an embodiment of the present disclosure.

Referring to FIG. 8, a timing diagram of any one program loop including a program phase and a verify phase is illustrated. Any one program loop of the program operation may be performed during first to sixth times t1 to t6. The first to fourth times t1 to t4 may constitute the program phase, the fourth to sixth times t4 to t6 may constitute the verify phase.

First, at the first time t1, a select voltage Von may be applied to a selected drain select line and a selected source select line Selected DSL/SSL to turn on select transistors DST/SST. In addition, a first voltage V1 may be applied to a selected word line Selected WL and an unselected word line Unselected WLs. A ground voltage GND may be applied to an unselected source select line Unselected SSLs and an unselected drain select line Unselected DSLs. When the ground voltage GND is applied, a source select transistor SST and a drain select transistor DST, which are connected to the unselected source select line Unselected SSLs and the unselected drain select line Unselected DSLs, may be turned off, and therefore, a program inhibit voltage may be applied to a channel of unselected strings.

In addition, at the second time t2, the first voltage V1 that is applied to the unselected word line Unselected WLs may be maintained, and a voltage level may increase from the first voltage V1 that is applied to the selected word line Selected WL to a program voltage Vpgm. The first voltage V1 may be a voltage with the same voltage level as a voltage level of a pass voltage Vpass or may be a voltage that has a voltage level that is higher than the voltage level of the pass voltage Vpass and has a voltage level that is lower than a voltage level of the program voltage Vpgm. The program voltage Vpgm may be applied to the selected word line Selected WL in a state in which a program allow voltage or the program inhibit voltage is applied to bit lines, so that a selected memory cell, among memory cells that are connected to the selected word line Selected WL, can be programmed.

At the third time t3, the pass voltage Vpass may be applied to all the word lines Selected WL and Unselected WLs. Furthermore, the pass voltage Vpass that is applied to all the word lines Selected WL and Unselected WLs may be applied during a certain time tVph. That is, after the program voltage Vpgm is applied to the selected word line Selected WL, voltage levels that are applied to all the word lines may be equally set before the verify phase is performed. The certain time tVph may be a pass voltage maintenance time. In addition, a channel initialization operation of the unselected strings may be performed during the pass voltage maintenance time. Specifically, while the pass voltage is applied to the memory cells that are connected to the selected word line WL, a select voltage Vs at which the source select transistor is turned on may be applied to the unselected source select line Unselected SSLs. In addition, the ground voltage may be applied to the unselected drain select line Unselected DSLs. In accordance with the embodiment of the present disclosure, a drain select transistor DST that is connected to a drain select line DSL of the unselected string is turned off, and a source select transistor SST that is connected to a source select line SSL of the unselected string is turned on. Thus, a channel potential can be discharged to only the side of the source select line SSL, and the channel of the unselected string can be initialized.

In addition, the channel initialization operation of the unselected string, which is performed at the third time t3, can minimize disturbance in the verify phase subsequently performed during the fourth to sixth times t4 to t6.

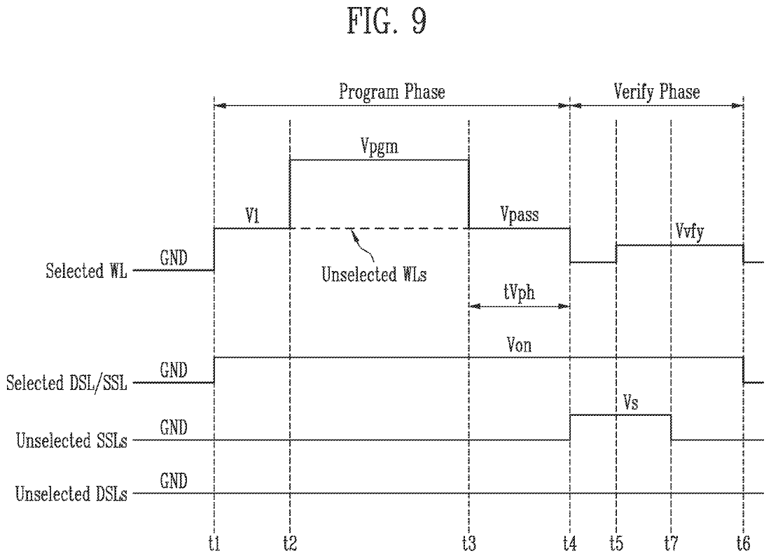

FIG. 9 is a timing diagram of a program operation in accordance with an embodiment of the present disclosure.

Referring to FIG. 9, the channel initialization operation of the unselected string may be performed in the verify phase.

Specifically, after the pass voltage Vpass is applied to all the word lines Selected WL and Unselected WLs, the select voltage Vs at which the source select transistor is turned on may be applied to the unselected source select line Unselected SSLs at the fourth time t4. In addition, the ground voltage may be applied to the unselected drain select line Unselected DSLs. In accordance with the embodiment of the present disclosure, the drain select transistor DST that is connected to the drain select line DSL of the unselected string may be turned off, and the source select transistor SST that is connected to the source select line SSL of the unselected string may be turned on. Thus, a channel potential may be discharged to only the side of the source select line SSL, and the channel of the unselected string may be initialized.

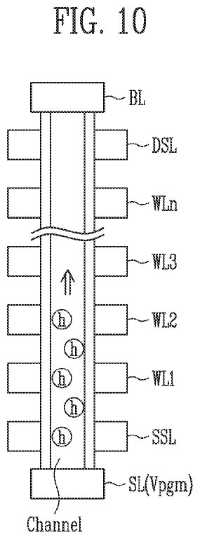

FIG. 10 is a sectional view of a string at any time during a program operation in accordance with an embodiment of the present disclosure.

Referring to FIG. 10, any one unselected string, among a plurality of strings, while a program voltage is being applied to a selected word line, is illustrated. As described in FIGS. 3 to 5, a plurality of memory blocks BLK1 to BLKz may share a source line SL. Hot holes \textcircled{h} may be introduced into a channel Channel of each of unselected strings by a program voltage Vpgm that is applied to the source line in a program operation on a selected memory block, among the plurality of memory blocks BLK1 to BLKz.

Specifically, while the program voltage is applied to a selected word line, a voltage with a level at which a source select transistor and a drain select transistor, which are connected to a source select line SSL and a drain select line DSL of an unselected string, are turned off may be applied to the source select transistor and the drain select transistor. That is, a channel of the unselected string may be electrically blocked from the source line SL and a bit line BL. When hot holes are introduced into the channel of the unselected string due to a Hot Carrier Injection (HCI) in the state in which the channel of the unselected string is electrically blocked from the source line SL and the bit line BL, the channel of the unselected string may be in a floating state.

In addition, when the channel of the unselected string is boosted by the program voltage Vpgm and a pass voltage Vpass, which are applied to the selected word line and unselected word lines, a channel potential of the unselected string may become high. When the channel potential of the unselected string becomes high, disturbance may occur in a verify operation that is to be subsequently performed. Therefore, in order to reduce disturbance due to the channel potential, it is necessary to initialize the channel of the unselected string.

In accordance with the embodiment of the present disclosure, the drain select transistor that is connected to the drain select line of the unselected string may be turned off, and the source select transistor that is connected to the source select line SSL of the unselected string may be turned on. Thus, the channel potential may be discharged to only the side of the source select line SSL.

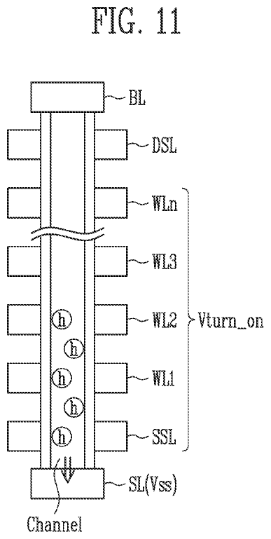

FIG. 11 is a sectional view of a string at any time during a program operation in accordance with an embodiment of the present disclosure.

Referring to FIG. 11, an operation in which a channel of an unselected string is initialized during a program operation is illustrated. Specifically, the channel initialization operation of the unselected string may be performed in a pass voltage maintenance period, after a period in which a program voltage is applied. In the channel initialization operation of the unselected string, a turn-on voltage may be applied to a source select transistor SST of unselected strings, and a ground voltage may be applied to a drain select transistor DST of the unselected strings. The source select transistor SST of unselected strings may be turned on, and the drain select transistor DST of the unselected strings may be turned off. In addition, a pass voltage at which memory cells are turned on is applied to a plurality of word lines WL1 to WLn in the pass voltage maintenance period, and therefore, a channel Channel of each of the unselected strings may be electrically connected to a source line SL, so that hot holes \textcircled{h} in the channel can be removed.

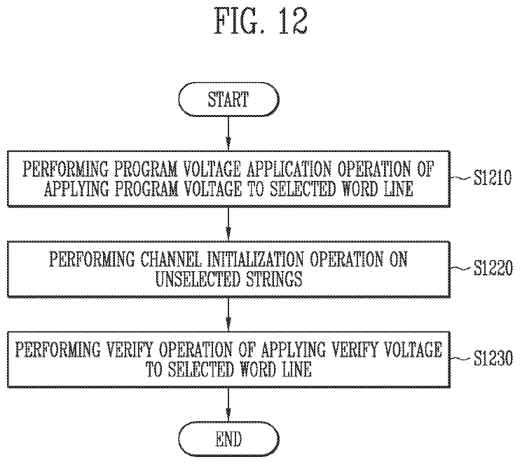

FIG. 12 is a flowchart illustrating an operating method of the memory device in accordance with an embodiment of the present disclosure.

Referring to FIG. 12, the memory device 100 may include a plurality of memory cells that are connected to a plurality of word lines and a plurality of strings. Furthermore, the memory device 100 may perform a program application operation that applies a program voltage to a selected word line (S1210). Specifically, the memory device 100 may apply the program voltage to a word line, among the plurality of word lines, corresponding to memory cells that are to store data, i.e., the selected word line.

Furthermore, the memory device 100 may perform a channel initialization operation on unselected strings (S1220). Specifically, the memory device 100 may apply a turn-on voltage to a source select line of the unselected strings, among the plurality of strings. Additionally, the memory device 100 may perform the channel initialization operation of the unselected strings by applying a ground voltage to a drain select line of the unselected strings, among the plurality of strings.

The memory device 100 may perform a verify operation that applies a verify operation to the selected word line (S1230). Specifically, the memory device 100 may perform the verify operation that applies, to the selected word line, the verify voltage for verifying a program state of memory cells that corresponds to the selected word line.

In accordance with an embodiment, the memory device 100 may apply a pass voltage to the selected word line when the memory device 100 performs the channel initialization operation on the unselected strings.

In accordance with an embodiment, the memory device 100 may apply the ground voltage to an unselected source select line while the memory device 100 applies the program voltage to the selected word line.

In accordance with an embodiment, the memory device 100 may apply the ground voltage to the unselected source select line while the memory device 100 applies the verify voltage to the selected word line.

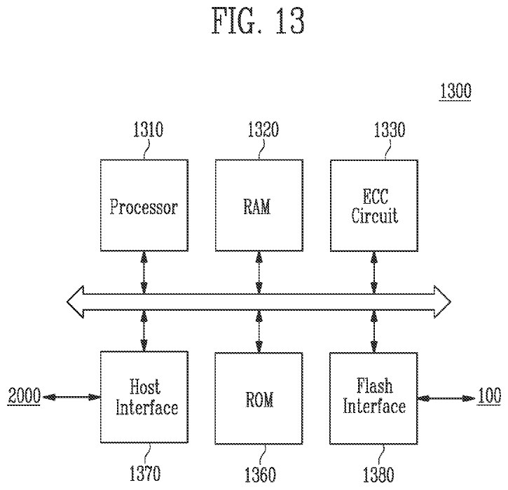

FIG. 13 is a diagram illustrating a memory controller in accordance with an embodiment of the present disclosure.

Referring to FIG. 13, the memory controller 1300 may include a processor 1310, a RAM 1320, and an ECC circuit 1330, a ROM 1360, a host interface 1370, and a flash interface 1380. The memory controller 1300, shown in FIG. 13, may be an embodiment of the memory controller 200 shown in FIG. 1.

The processor 1310 may communicate with the host 2000 by using the host interface 1370 and may perform a logical operation to control an operation of the memory controller 1300. For example, the processor 1310 may load a program command, a data file, a data structure, and the like, based on a request received from the host 2000 or an external device, and perform various operations or generate a command and an address. For example, the processor 1310 may generate various commands necessary for a program operation, a read operation, an erase operation, a suspend operation, and a parameter setting operation.

Furthermore, the processor 1310 may perform a function of a Flash Translation Layer (FTL). The processor 250 may translate a Logical Block Address (LBA) provided by the host 2000 into a Physical Block Address (PBA) through the FTL. The FTL may receive an LBA, input by using a mapping table, to translate the LBA into a PBA. Several address mapping methods of the FTL exist according to mapping units. A representative address mapping method may include a page mapping method, a block mapping method, and a hybrid mapping method.

Furthermore, the processor 1310 may generate a command without any request from the host 2000. For example, the processor 1310 may generate a command for background operations, such as operations for wear leveling of the memory device 100 and operations for garbage collection of the memory device 100.

The RAM 1320 may be used as a buffer memory, a working memory, or a cache memory of the processor 1310. Furthermore, the RAM 1320 may store codes and commands, which the processor 1310 executes. The RAM 1320 may store data processed by the processor 1310. Additionally, the RAM 1320 may be implemented, including a Static RAM (SRAM) or a Dynamic RAM (DRAM).

The ECC circuit 1330 may detect an error in a program operation or a read operation and may correct the detected error. Specifically, the ECC circuit 1330 may perform an error correction operation according to an Error Correction Code (ECC). Furthermore, the ECC circuit 1330 may perform ECC encoding based on data to be written to the memory device 100. The data on which the ECC encoding is performed may be transferred to the memory device 100 through the flash interface 1380. Additionally, the ECC circuit 1330 may perform ECC decoding on data that is received from the memory device 100 through the flash interface 1380.

The ROM 1360 may be used as a storage unit to store various information that is necessary to operate the memory controller 1300. Specifically, the ROM 1360 may include a map table, and physical-to-logical address information and logical-to-physical address information may be stored in the map table. Furthermore, the ROM 1360 may be controlled by the processor 1310.

The host interface 1370 may include a protocol for exchanging data between the host 2000 and the memory controller 1300. Specifically, the host interface 1370 may communicate with the host 2000 through at least one of the following various interface protocols: a Universal Serial Bus (USB) protocol, a Multi-Media Card (MMC) protocol, a Peripheral Component Interconnection (PCI) protocol, a PCI-Express (PCI-E) protocol, an Advanced Technology Attachment (ATA) protocol, a Serial-ATA protocol, a Parallel-ATA protocol, a Small Computer System Interface (SCSI) protocol, an Enhanced Small Disk Interface (ESDI) protocol, an Integrated Drive Electronics (IDE) protocol, a private protocol, and the like.

The flash interface 1380, under the control of the processor 1310, may communicate with the memory device 100 by using a communication protocol. Specifically, the flash interface 1380 may communicate a command, an address, and data with the memory device 100 through a channel. For example, the flash interface 1380 may include a NAND interface.

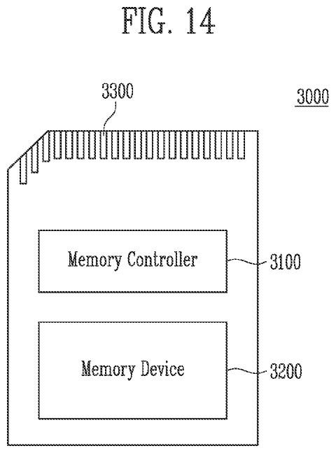

FIG. 14 is a diagram illustrating a memory card system in accordance with an embodiment of the present disclosure.

Referring to FIG. 14, the memory card system 3000 may include a memory controller 3100, a memory device 3200, and a connector 3300.

The memory controller 3100 may be connected to the memory device 3200. The memory controller 3100 may access the memory device 3200. For example, the memory controller 3100 may control read, write, erase, and background operations on the memory device 3200. The memory controller 3100 may provide an interface between the memory device 3200 and a host. Furthermore, the memory controller 3100 may drive firmware that controls the memory device 3200.

For example, the memory controller 3100 may include components, such as a Random Access Memory (RAM), a processing unit, a host interface, a memory interface, and the error corrector 233.

The memory controller 3100 may communicate with an external device through the connector 3300. The memory controller 3100 may communicate with the external device (e.g., the host) according to a specific communication protocol. Exemplarily, the memory controller 3100 may communicate with the external device through at least one of the following various communication protocols: a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), firewire, a Universal Hash Storage (UFS), Wi-Fi, Bluetooth, NVMe, and the like.

Exemplarily, the memory device 3200 may be implemented with various nonvolatile memory devices, such as an Electrically Erasable and Programmable ROM (EEPROM), a NAND flash memory, a NOR flash memory, a Phase-change RAM (PRAM), a Resistive RAM (ReRAM), a Ferroelectric RAM (FRAM), and a Spin Torque Transfer magnetic RAM (STT-MRAM).

The memory controller 3100 and the memory device 3200 may be integrated into a single semiconductor device, to constitute a memory card. For example, the memory controller 3100 and the memory device 3200 may constitute a memory card, such as a PC card (Personal Computer Memory Card International Association (PCMCIA)), a Compact Flash (CF) card, a Smart Media Card (SM and SMC), a memory stick, a Multi-Media Card (MMC, RS-MMC, MMCmicro and eMMC), an SD card (SD, miniSD, microSD and SDHC), and a Universal Flash Storage (UFS).

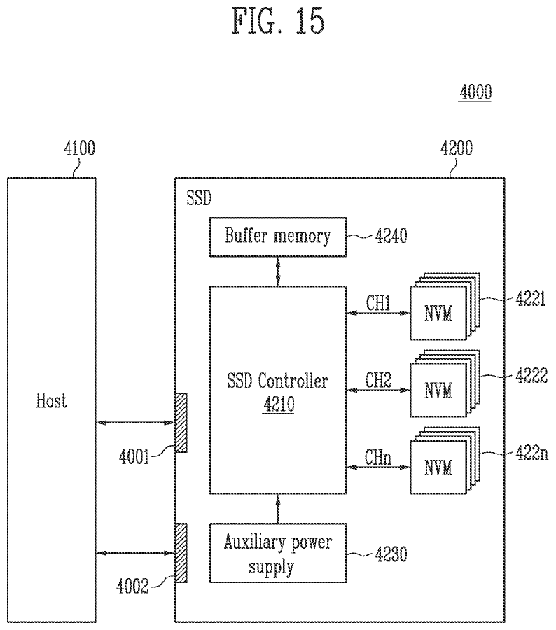

FIG. 15 is a diagram illustrating a Solid State Drive (SSD) in accordance with an embodiment of the present disclosure.

Referring to FIG. 15, the SSD system 4000 may include a host 4100 and an SSD 4200. The SSD 4200 may exchange a signal SIG with the host 4100 through a signal connector 4001 and may receive power PWR through a power connector 4002. The SSD 4200 may include an SSD controller 4210, a plurality of flash memories 4221 to 422n, an auxiliary power supply 4230, and a buffer memory 4240.

In an embodiment, the SSD controller 4210 may serve as the memory controller 200, described with reference to FIG. 1. The SSD controller 4210 may control the plurality of flash memories 4221 to 422n in response to a signal SIG that is received from the host 4100. Exemplarily, the signal SIG may be a signal based on an interface between the host 4100 and the SSD 4200. For example, the signal SIG may be a signal that is defined by at least one of the following interfaces: a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (DATA), a Small Computer System Interface (SCSI), an Enhanced Small Disk Interface (ESDI), an Integrated Drive Electronics (IDE), a firewire, a Universal Flash Storage (UFS), a WI-FI, a Bluetooth, an NVMe, and the like.

The auxiliary power supply 4230 may be connected to the host 4100 through the power connector 4002. The auxiliary power supply 4230 may receive power PWR that is input from the host 4100 and may charge the power PWR. When the supply of power from the host 4100 is not smooth, the auxiliary power supply 4230 may provide power for the SSD 4200. Exemplarily, the auxiliary power supply 4230 may be located in the SSD 4200 or may be located outside of the SSD 4200. For example, the auxiliary power supply 4230 may be located on a main board and may provide auxiliary power to the SSD 4200.

The buffer memory 4240 may operate as a buffer memory of the SSD 4200. For example, the buffer memory 4240 may temporarily store data that is received from the host 4100 or data that is received from the plurality of flash memories 4221 to 422n, or the buffer memory 4240 may temporarily store meta data (e.g., a mapping table) of the flash memories 4221 to 422n. The buffer memory 4240 may include volatile memories, such as a DRAM, an SDRAM, a DDR SDRAM, an LPDDR SDRAM, and a GRAM or nonvolatile memories such as a FRAM, a ReRAM, an STT-MRAM, and a PRAM.

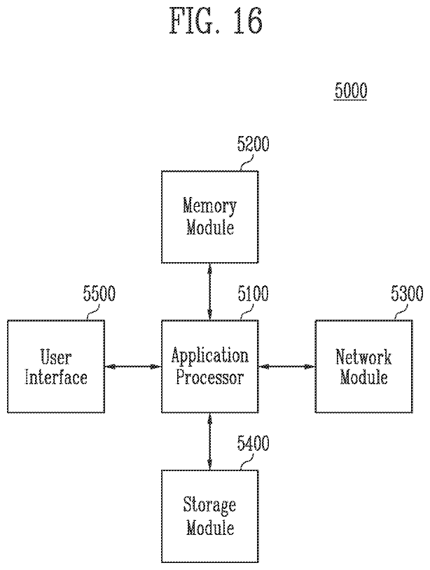

FIG. 16 is a diagram illustrating a user system in accordance with an embodiment of the present disclosure.

Referring to FIG. 16, the user system 5000 may include an application processor 5100, a memory module 5200, a network module 5300, a storage module 5400, and a user interface 5500.

The application processor 5100 may drive components that are included in the user system 5000, an operating system (OS), a user program, or the like. Exemplarily, the application processor 5100 may include controllers that control components that are included in the user system 5000, interfaces, a graphic engine, and the like. The application processor 5100 may be provided as a System-on-Chip (SoC).

The memory module 5200 may operate as a main memory, working memory, buffer memory or cache memory of the user system 5000. The memory module 5200 may include volatile random access memories, such as a DRAM, an SDRAM, a DDR SDRAM, a DDR2 SDRM, a DDR3 SDRAM, an LPDDR SDRAM, an LPDDR2 SDRAM, and an LPDDR3 SDRAM or nonvolatile random access memories such as a PRAM, a ReRAM, an MRAM, and a FRAM. Exemplarily, the application processor 5100 and the memory module 5200 may be provided as one semiconductor package by being packaged based on a Package on Package (PoP).

The network module 5300 may communicate with external devices. Exemplarily, the network module 5300 may support wireless communications, such as Code Division Multiple Access (CDMA), Global System for Mobile communication (GSM), Wideband CDMA (WCDMA), CDMA-2000, Time Division Multiple Access (TDMA), Long Term Evolution (LTE), Wimax, WLAN, UWB, Bluetooth, and Wi-Fi. Exemplarily, the network module 5300 may be included in the application processor 5100.

The storage module 5400 may store data. For example, the storage module 5400 may store data that is received from the application processor 5100. Alternatively, the storage module 5400 may transmit data that is stored therein to the application processor 5100. Exemplarily, the storage module 5400 may be implemented with a nonvolatile semiconductor memory device, such as a Phase-change RAM (PRAM), a Magnetic RAM (MRAM), a Resistive RAM (RRAM), a NAND flash, a NOR flash, or a NAND flash with a three-dimensional structure. Exemplarily, the storage module 5400 may be provided as a removable drive such as a memory card of the user system 5000 or an external drive.

Exemplarily, the storage module 5400 may include a plurality of nonvolatile memory devices, and the plurality of nonvolatile memory devices may operate identically to the memory device 100, described with reference to FIGS. 1 to 5. The storage module 4400 may operate identically to the storage device 1000, described with reference to FIG. 1.

The user interface 5500 may include interfaces for inputting data or commands to the application processor 5100 or outputting data to an external device. Exemplarily, the user interface 5500 may include user input interfaces, such as a keyboard, a keypad, a button, a touch panel, a touch screen, a touch pad, a touch ball, a camera, a microphone, a gyroscope sensor, a vibration sensor and a piezoelectric element. The user interface 4500 may include user output interfaces, such as a Liquid Crystal Display (LCD), an Organic Light Emitting Diode (OLED) display device, an Active Matrix OLED (AMOLED) display device, an LED, a speaker, and a monitor.

In accordance with the present disclosure, there can be provided a memory device for performing an improved program operation and an operating method of the memory device.

While the present disclosure has been shown and described with reference to certain exemplary embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described exemplary embodiments but should be determined by not only the appended claims but also the equivalents thereof.

In the above-described embodiments, all steps may be selectively performed or part of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the exemplary embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A memory device comprising:
a memory cell array including a plurality of memory cells that are connected to a plurality of word lines and a plurality of strings; and
a peripheral circuit configured to perform a program operation on selected memory cells, among the plurality of memory cells, connected to a selected word line,
wherein, while the peripheral circuit applies a pass voltage to the selected word line during the program operation to turn on the selected memory cells, the peripheral circuit is configured to apply a select voltage to an unselected source line to turn on a source select transistor and configured to apply a ground voltage to an unselected drain select line.

2. The memory device of claim 1,
wherein the program operation includes:
a program phase including a period in which the program voltage is applied to the selected word line and a period in which the pass voltage is applied to the selected word line,
and a verify phase including a period in which a verify voltage that verifies a program state of the selected memory cells is applied to the selected word line.

3. The memory device of claim 2, wherein, while the peripheral circuit applies the program voltage to the selected word line, the peripheral circuit applies the ground voltage to the unselected source select line.

4. The memory device of claim 2, wherein, while the peripheral circuit applies the verify voltage to the selected word line, the peripheral circuit applies the ground voltage to the unselected source select line.

5. The memory device of claim 1, wherein the peripheral circuit includes a voltage generator configured to generate an internal voltage that includes the pass voltage and the select voltage, which are used to perform the program operation.

6. The memory device of claim 1, comprising a control logic configured to control the peripheral circuit to apply a voltage to the plurality of word lines and the plurality of strings.

7. The memory device of claim 1, wherein a voltage level of the select voltage is higher than a voltage level of a threshold voltage of the source select transistor, and
wherein the voltage level of the select voltage is lower than a voltage level of the pass voltage.

8. A method for operating a memory device with a plurality of memory cells that are connected to a plurality of word lines and a plurality of strings, the method comprising:
performing a program voltage application operation that applies a program voltage to a selected word line, among the plurality of word lines;
performing a channel initialization operation on unselected strings, among the plurality of strings, by applying a turn-on voltage to a source select line of the unselected strings, among the plurality of strings, and applying a ground voltage to a drain select line of the unselected strings; and
performing a verify operation that applies a verify voltage to the selected word line.

9. The method of claim 8, wherein the performing of the channel initialization operation further includes applying a pass voltage to the selected word line to turn on the selected memory cells that correspond to the selected word line.

10. The method of claim 8, wherein, in performing the program voltage application operation, the ground voltage is applied to the unselected source select line while the program voltage is applied to the selected word line.

11. The method of claim 8, wherein, in performing the verify operation, the ground voltage is applied to the unselected source select line while the verify voltage is applied to the selected word line.

12. The method of claim 8, wherein a voltage level of the turn-on voltage is higher than a voltage level of a threshold voltage of the source select transistor, and
wherein the voltage level of the turn-on voltage is lower than a voltage level of a pass voltage that is applied to the selected word line.

13. A memory device comprising:
a memory cell array including a plurality of memory cells that are connected to a plurality of word lines and a plurality of strings; and
a peripheral circuit configured to:
apply a program voltage to a selected word line, among the plurality of word lines, and apply a pass voltage to the selected word line to turn on selected memory cells that correspond to the selected word line; and then
apply a select voltage to an unselected source select line to turn on a source select transistor that corresponds to an unselected source select line and apply a ground voltage to an unselected drain select line.

14. The memory device of claim 13, wherein, while the peripheral circuit applies the pass voltage to the selected word line to turn on the selected memory cells that correspond to the selected word line, the peripheral circuit is configured to apply the ground voltage to the unselected source select line and the unselected drain select line.

15. The memory device of claim 13, wherein the peripheral circuit further includes a voltage generator configured to generate an internal voltage that includes the program voltage, the pass voltage, and the select voltage.

16. The memory device of claim 13, comprising a control logic configured to control the peripheral circuit to apply a voltage to the plurality of word lines and the plurality of strings.
